(19) United States
(12) Patent Application Publication
(10) Pub. No.: US 2023/0352904 A1
(43) Pub. Date: Nov. 2, 2023

(54) LIGHT-EMITTING DEVICE AND MOUNTING MEMBER

(71) Applicant: NICHIA CORPORATION, Anan-shi (JP)

(72) Inventors: Kiyoshi ENOMOTO, Komatsushima-shi (JP); Masanori UEMURA, Anan-shi (JP)

(21) Appl. No.: 18/308,602

(22) Filed: Apr. 27, 2023

(30) Foreign Application Priority Data
Apr. 28, 2022 (JP) 2022-074740
Feb. 22, 2023 (JP) 2023-025660

(51) Int. Cl. H01S 5/02315; H01S 5/02345; H01S 5/40; H01S 5/02

(52) U.S. Cl. CPC H01S 5/02315; H01S 5/02345; H01S 5/4025; H01S 5/0208

(57) ABSTRACT

A mounting member includes a substrate, a first metal layer, and a second metal layer. The substrate has an insulating property and has a first surface and a second surface. The substrate has a shape in which a length in a second direction perpendicular to a first direction is greater than a width in the first direction in a plan view. The first metal layer is arranged on the first surface. The second metal layer is arranged on the second surface. A width of the second metal layer is smaller than a width of the first metal layer in the first direction. A difference between a length of the first metal layer and a length of the second metal layer in the second direction is smaller than a difference between the width of the first metal layer and the width of the second metal layer in the first direction.

### CROSS-REFERENCE TO RELATED APPLICATION

This application claims priority to Japanese Patent Application No. 2022-74740, filed on Apr. 28, 2022, and Japanese Patent Application No. 2023-25660 filed on Feb. 22, 2023, the disclosures of which are hereby incorporated herein by reference in their entirety.

### BACKGROUND OF THE INVENTION

The present invention relates to a light-emitting device and a mounting member.

A light-emitting device in which a laser element is mounted on a submount is known. An electronic component such as a laser element is often placed on a mounting member such as a submount and incorporated in a device.

Japanese Unexamined Patent Application Publication No. 2021-44468 discloses a submount in which a laser element is mounted. The submount includes an AIN substrate and a copper plating which is formed on each of the front and rear surfaces of the AIN substrate.

### SUMMARY OF THE INVENTION

There is room for improvement in mounting members to reduce the size of devices.

According to one embodiment, a light-emitting device includes a submount and a semiconductor laser element. The submount includes a substrate, a first metal layer and a second metal layer. The substrate has an insulating property. The substrate has a first surface and a second surface located on a side opposite to the first surface. The substrate has a shape in which a length in a second direction perpendicular to a first direction is greater than a width in the first direction in a plan view as seen along a direction perpendicular to the first surface. The first metal layer is arranged on the first surface of the substrate. The second metal layer is arranged on the second surface of the substrate. The semiconductor laser element is arranged on a side of the submount on which the first metal layer is arranged. A width of the second metal layer is smaller than a width of the first metal layer in the first direction. A difference between a length of the first metal layer and a length of the second metal layer in the second direction is smaller than a difference between the width of the first metal layer and the width of the second metal layer in the first direction.

According to another embodiment, a mounting member includes a substrate, a first metal layer, and a second metal layer. The substrate has an insulating property. The substrate has a first surface and a second surface on a side opposite to the first surface. The substrate has a shape in which a length in a second direction perpendicular to a first direction is greater than a width in the first direction in a plan view as seen along a direction perpendicular to the first surface. The first metal layer is arranged on the first surface. The second metal layer is arranged on the second surface. A width of the second metal layer is smaller than a width of the first metal layer in the first direction. A difference between a length of the first metal layer and a length of the second metal layer in the second direction is smaller than a difference between the width of the first metal layer and the width of the second metal layer in the first direction.

According to certain embodiments of the disclosure, a mounting member that contributes to reduction in size of devices can be provided.

### BRIEF DESCRIPTION OF DRAWINGS

FIG. 1 is a perspective view of a light-emitting device according to a first embodiment and a second embodiment.

FIG. 2 is a top view of the light-emitting device according to the first embodiment and the second embodiment.

FIG. 3 is a top view for illustrating each component disposed inside the light-emitting device according to the first embodiment.

FIG. 4 is a cross-sectional view taken along a cross-sectional line IV-IV of FIG. 2.

FIG. 5 is a top view of a mounting member according to the first embodiment and the second embodiment.

FIG. 6 is a cross-sectional view of the mounting member taken along a cross-sectional line VI-VI of FIG. 5.

FIG. 7 is a cross-sectional view of the mounting member taken along a cross-sectional line VII-VII of FIG. 5.

FIG. 8 is a schematic view for illustrating an example of a state of bonding a submount in the light-emitting device according to the first embodiment and the second embodiment.

FIG. 9 is a schematic view for illustrating another example of a state of bonding the submount in the light-emitting device according to the first embodiment and the second embodiment.

FIG. 10 is a schematic view for illustrating an undesirable state of bonding the submounts.

FIG. 11 is a top view for illustrating each component disposed inside the light-emitting device according to the second embodiment.

FIG. 12 is a cross-sectional view taken along a cross-sectional line XII-XII of FIG. 11.

FIG. 13 is an enlarged view of a second submount in the cross-sectional view of FIG. 12.

FIG. 14 is a schematic view for illustrating a second metal layer of a mounting member according to a modification.

FIG. 15 is a schematic view for illustrating a second metal layer of a mounting member according to another modification.

FIG. 16 is a perspective view of a light-emitting device according to a third embodiment.

FIG. 17 is a top view of the light-emitting device according to the third embodiment.

FIG. 18 is a top view for illustrating each component disposed inside the light-emitting device according to the third embodiment.

FIG. 19 is a cross-sectional view taken along a cross-sectional line XIX-XIX of FIG. 18.

FIG. 20 is a top view of a mounting member according to the third embodiment.

FIG. 21 is a bottom view of the mounting member according to the third embodiment.

FIG. 22 is a schematic view for illustrating an example of a state of bonding a submount in the light-emitting device according to the third embodiment.

### DETAILED DESCRIPTION

In this description or the scope of the claims, polygons such as triangles and quadrangles, including shapes in which the corners of the polygon are rounded, chamfered, beveled, coved, or the like, are referred to as polygons. Furthermore, a shape obtained by processing not only the corners (ends of sides), but also an intermediate portion of a side is similarly referred to as a polygon. That is, a shape that is partially processed while remaining a polygon shape as a base is included in the interpretation of “polygon” described in this description and the scope of the claims.

The same applies not only to polygons but also to words representing specific shapes such as trapezoids, circles, protrusions, and recessions. Furthermore, the same applies when dealing with each side forming that shape. That is, even if processing is performed on a corner or an intermediate portion of a certain side, the interpretation of “side” includes the processed portion. Note that when a “polygon” or “side” not partially processed is to be distinguished from a processed shape, “strict” will be added to the description as in, for example, “strict quadrangle”.

Further, in the description and the claims, descriptions such as upper and lower (upward/downward), left and right, top and bottom, front and back (forward/backward), and near and far are used merely to describe the relative relationship of positions, orientations, directions, and the like, and the expressions need not necessarily match an actual relationship at the time of use.

In the drawings, directions such as an X direction, a Y direction, and a Z direction may be indicated by using arrows. The directions of the arrows are consistent across multiple drawings of the same embodiment. In the drawings, the direction of the arrows denoted by X, Y, and Z are referred to as a positive direction, and the direction opposite to the positive direction is referred to as a negative direction. For example, the direction indicated by X at the end of the arrow is the X direction and the positive direction. Note that a direction being the X direction and the positive direction is referred to as a “positive direction of X,” and a direction opposite to the positive direction of X is referred to as a “negative direction of X.” The same applies to the Y direction and the Z direction.

In this description, “member” and “portion” may be used to describe, for example, a component and the like. The term “member” refers to an object physically treated alone. The object physically treated alone can be an object treated as one component in a manufacturing step. On the other hand, the term “portion” refers to an object that may not be physically treated alone. For example, the term “portion” is used when a part of one member is partially regarded.

Note that the distinction between “member” and “portion” described above does not intend to consciously limit the scope of rights in interpretation of the doctrine of equivalents. In other words, even when a component is described as “member” in the claims, this does not mean that the applicant recognizes that physically treating the component alone is essential to the application of the present invention.

In the description or in the claims, when a plurality of certain components are distinguished from each other, they may be distinguished by adding the terms “first” and “second” to the beginning of the name of the component. There may be cases where the objects to be distinguished between the description and the claims are different. Thus, even when a component in the claims is given the same term as that in the description, the object indicated by that component may not be consistent between the description and the claims.

For example, when there are components distinguished by adding the terms “first”, “second”, and “third” in the description, and when the components given the terms “first” and “third” in the description are described in the claims, these components may be distinguished by being denoted as “first” and “second” in the claims for ease of understanding. In this case, the components with the term “first” and “second” in the claims refer to the components with the term “first” and “third” in the description, respectively. Note that this rule is not limited to being applied to the components and also applies to other objects in a reasonable and flexible manner.

Embodiments for implementing the present invention will be described below. Furthermore, specific embodiments for implementing the present invention will be described below with reference to the drawings. Note that embodiments for implementing the present invention are not limited to the specific embodiments. In other words, the embodiments illustrated in the drawings are not the only form in which the present invention is realized. Note that sizes, positional relationships, and the like of members illustrated in the drawings may sometimes be exaggerated to facilitate understanding.

### First Embodiment

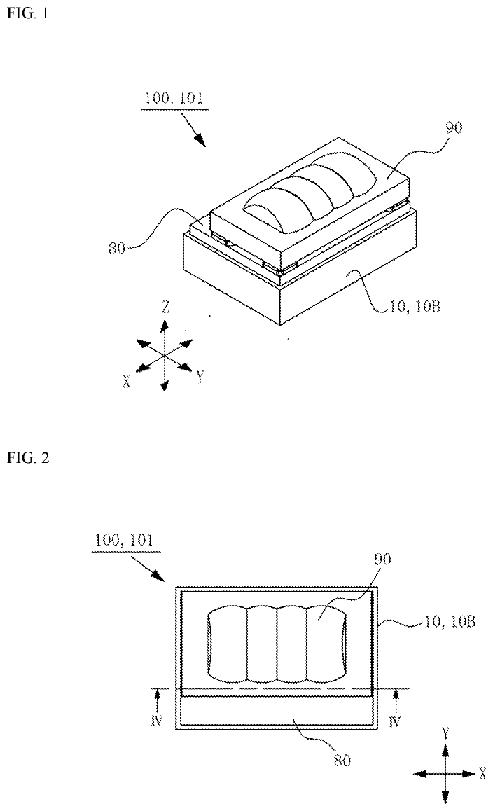

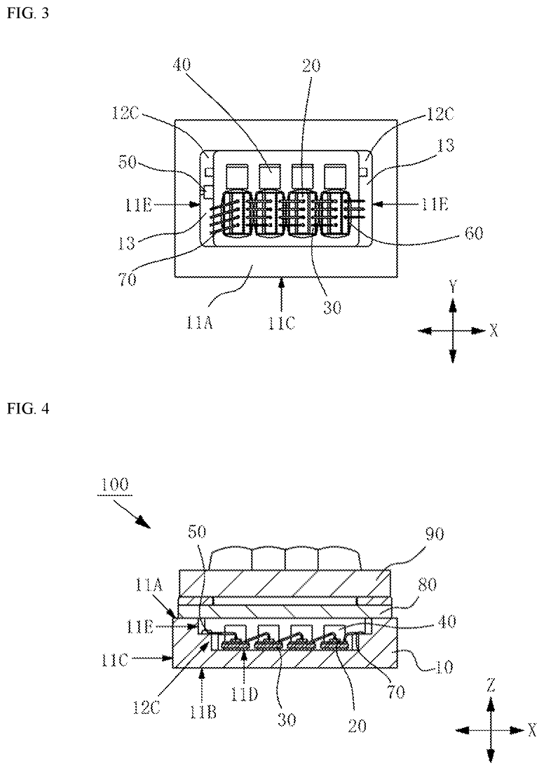

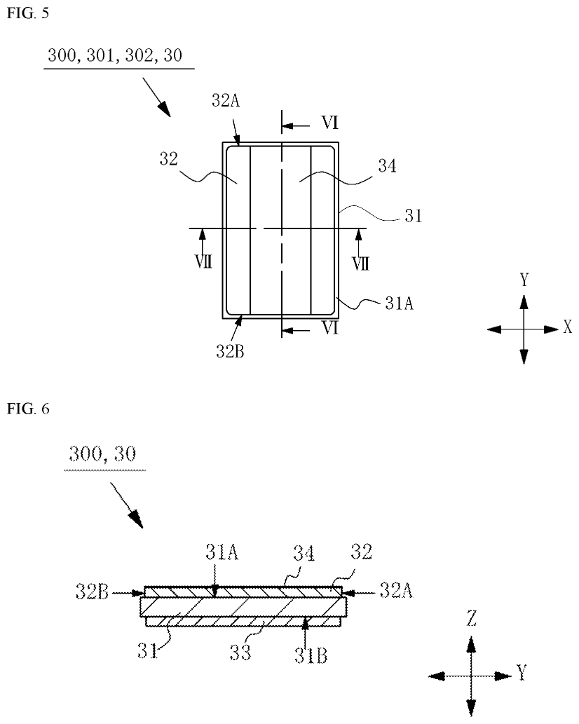

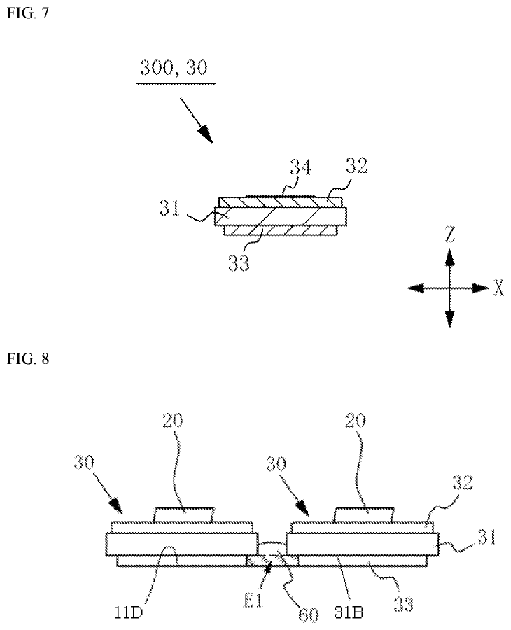

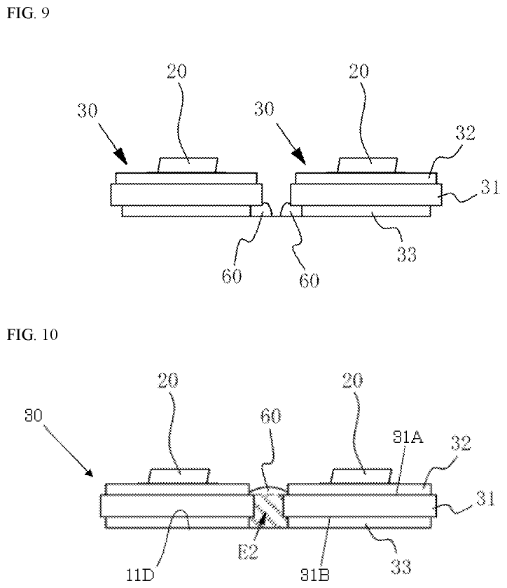

FIGS. 1 to 10 are diagrams illustrating an exemplary embodiment of a light-emitting device 100 and a mounting member 300 according to the first embodiment. FIG. 1 is a perspective view of the light-emitting device 100. FIG. 2 is a top view of the light-emitting device 100. FIG. 3 is a top view illustrating each component disposed inside the light-emitting device 100. FIG. 4 is a cross-sectional view taken along a cross-sectional line IV-IV of FIG. 2. Note that in FIG. 4, a bonding portion 60 illustrated in FIG. 3 is omitted. FIG. 5 is a top view of the mounting member 300 (a submount 30). FIG. 6 is a cross-sectional view of the mounting member 300 taken along a cross-sectional line VI-VI of FIG. 5. FIG. 7 is a cross-sectional view of the mounting member 300 taken along a cross-sectional line VII-VII of FIG. 5. FIG. 8 is a schematic view for illustrating an example of a state of bonding the submount 30 in the light-emitting device 100. Note that the hatching in FIG. 8 represents a region E1. FIG. 9 is a schematic view for illustrating another example of a state of bonding the submount 30 in the light-emitting device 100. FIG. 10 is a schematic view for illustrating an example of an undesirable state of bonding submounts. Note that the hatching in FIG. 10 represents a region E2. FIG. 10 illustrates merely an example intended for assistance in understanding the invention, the technical problems to be solved by the present invention are not limited to the state illustrated in FIG. 10, and the effects of the present invention may not be confirmed only by comparison with the state illustrated in FIG. 10.

The light-emitting device 100 includes a plurality of components. The plurality of components provided in the light-emitting device 100 include a base 10, one or a plurality of semiconductor laser elements 20, one or a plurality of submounts 30, one or a plurality of reflective members 40, one or a plurality of protective elements 50, one or a plurality of bonding portions 60, a plurality of wiring lines 70, a lid member 80, and a lens member 90.

Note that the light-emitting device 100 may include a component other than the components described above. For example, the light-emitting device 100 may further include a light-emitting element in addition to the one or the plurality of semiconductor laser elements 20. The light-emitting device 100 may not include some of the components described above.

The mounting member 300 is a member on which an electronic component such as a semiconductor laser element is mounted. The submount 30 provided in the light-emitting device 100 is a specific embodiment of the mounting member 300. Note that the electronic component mounted on the mounting member 300 is not limited to the semiconductor laser element, and may be other light-emitting elements such as a light-emitting diode, or may be other than light-emitting elements.

First, each of the components of the light-emitting device 100 will be described, and then the light-emitting device 100 will be described.

### Base 10

The base 10 includes an upper surface 11A, a lower surface 11B, and one or a plurality of outer lateral surfaces 11C. In a top view, an outer edge of the base 10 has a rectangular shape. This rectangular shape may be a shape with long sides and short sides. In the illustrated base 10, a long side direction of the rectangle is the same direction as the X direction, and a short side direction is the same direction as the Y direction. Note that the outer edge of the base 10 in the top view may not have a rectangular shape.

A recessed shape is formed in the base 10. A recessed shape being recessed downward from the upper surface 11A is formed from the upper surface 11A. A recess is defined by the recessed shape of the base 10. The recess is surrounded by the upper surface 11A in the top view.

An inner edge of the upper surface 11A defines an outer edge of the recess. In other words, an inner edge shape of the upper surface 11A and an outer edge shape of the recess match each other. In the top view, an outer edge of the recess has a rectangular shape. This rectangular shape may be a shape with long sides and short sides. In the illustrated base 10, a long side direction of the rectangle is the same direction as the X direction, and a short side direction is the same direction as the Y direction. Note that the outer edge of the recess may not have a rectangular shape.

The base 10 includes a mounting surface 11D. The base 10 includes one or a plurality of inner lateral surfaces 11E. The mounting surface 11D is located below the upper surface 11A and above the lower surface 11B. The mounting surface 11D is an upper surface. Thus, it can be said that the mounting surface 11D is an upper surface different from the upper surface 11A. The mounting surface 11D is a flat surface having a shape with a width in the X direction greater than a length in the Y direction.

The one or the plurality of inner lateral surfaces 11E are located above the mounting surface 11D. The one or the plurality of inner lateral surfaces 11E meet the upper surface 11A. The mounting surface 11D and the one or the plurality of inner lateral surfaces 11E are included in a plurality of surfaces that define the recess of the base 10. The one or the plurality of inner lateral surfaces 11E define the outer edge shape of the recess.

The one or the plurality of inner lateral surfaces 11E are provided perpendicular to the mounting surface 11D. The description of “perpendicular” here allows a difference within ±3 degrees. Note that the inner lateral surface 11E may not be perpendicular to the mounting surface 11D.

The base 10 includes one or a plurality of stepped portions 12C. The stepped portion 12C includes an upper surface and an inner lateral surface that meets the upper surface and extends downward from the upper surface. The surface included in the stepped portion 12C does not include an inner lateral surface extending upward from the upper surface. The upper surface of the stepped portion 12C meets the inner lateral surface 11E. The inner lateral surface 11E extends upward from the upper surface of the stepped portion 12C. The inner lateral surface of the stepped portion 12C meets the mounting surface 11D.

The stepped portion 12C is formed along a part or the whole of the inner lateral surface 11E in the top view. The one or the plurality of stepped portions 12C are formed inside the upper surface 11A in the top view. The one or the plurality of stepped portions 12C are formed inside the one or the plurality of inner lateral surfaces 11E in the top view.

The base 10 may include the plurality of stepped portions 12C. Each of the plurality of stepped portions 12C is formed along the inner lateral surface 11E in the top view. The plurality of stepped portions 12C include the stepped portion 12C formed along the inner lateral surface 11E across an entire length of the inner lateral surface 11E in the top view.

The plurality of stepped portions 12C include the stepped portion 12C formed along a first inner lateral surface 11E (hereinafter referred to as first stepped portion), and the stepped portion 12C formed along a second inner lateral surface 11E (hereinafter referred to as second stepped portion) in the top view. The first inner lateral surface 11E and the second inner lateral surface 11E face each other. The first inner lateral surface 11E and the second inner lateral surface 11E are lateral surfaces extending in the Y direction.

The first stepped portion 12C may be formed along only the first inner lateral surface 11E. The second stepped portion 12C may be formed along only the second inner lateral surface 11E. The plurality of stepped portions 12C can be formed of only the first stepped portion 12C and the second stepped portion 12C. Note that the stepped portion 12C may be provided which is formed along a plurality of the joined inner lateral surfaces 11E not along only a single inner lateral surface 11E.

The first stepped portion 12C illustrated in FIG. 3 is formed along only the first inner lateral surface 11E, and is not formed along the inner lateral surface 11E that meets the first inner lateral surface 11E. Even when a portion of the first stepped portion 12C is joined with a portion of the inner lateral surface 11E that meets the first inner lateral surface 11E as a result of being formed along the first inner lateral surface 11E, this does not mean that the first stepped portion 12C is formed along the inner lateral surface 11E that meets the first inner lateral surface 11E. The same applies to the entire stepped portion 12C including the second stepped portion 12C.

One or a plurality of wiring layers 13 are provided at the upper surface of the stepped portion 12C. The wiring layer 13 is electrically connected to other wiring layers via a wiring line passing inside the base 10. Other wiring layers are provided at the lower surface of the base 10, for example. Note that the wiring layer 13 may be electrically connected to the wiring layer provided at the upper surface 11A or the outer lateral surface 11C.

The plurality of wiring layers 13 may be provided at the upper surface of the one or the plurality of stepped portions 12C. The one or the plurality of wiring layers 13 may be provided at each of the plurality of stepped portions 12C. Note that the portion, of the base 10, in which the wiring layer 13 is provided may not be limited to the stepped portion 12C.

The base 10 can be formed using ceramic as a main material. The base 10 may be formed by bonding a bottom member that is formed using metal or a composite containing metal as a main material and includes the mounting surface 11D, and a frame member that is formed using ceramic as a main material and includes the wiring pattern 13.

Here, the main material refers to a material that occupies the greatest ratio of a target formation in terms of weight or volume. Note that, when a target formation is formed of one material, that material is the main material. That is, when a certain material is the main material, the percentage of that material may be 100%.

Examples of the ceramic include aluminum nitride, silicon nitride, aluminum oxide, and silicon carbide. Examples of the metal include copper, aluminum, and iron. As the composite containing metal, copper molybdenum, a copper-diamond composite material, copper tungsten, and the like can be used.

### Semiconductor Laser Element 20

The semiconductor laser element 20 includes a light emission surface from which light is emitted. The semiconductor laser element 20 includes an upper surface, a lower surface, and a plurality of lateral surfaces. The upper surface or the lateral surface of the semiconductor laser element 20 is the light emission surface. The semiconductor laser element 20 includes one or a plurality of the light emission surfaces.

The upper surface of the semiconductor laser element 20 has a rectangular shape having long sides and short sides. A lateral surface having a short side of the rectangle may be the light emission surface. Note that the shape of the upper surface of the semiconductor laser element 20 may not be rectangular.

A single emitter-semiconductor laser element can be used for the semiconductor laser element 20. A multi-emitter semiconductor laser element including a plurality of emitters can be used for the semiconductor laser element 20.

For the semiconductor laser element 20, for example, a light-emitting element that emits blue light, a light-emitting element that emits green light, or a light-emitting element that emits red light can be used. Note that a light-emitting element that emits light of other colors or wavelengths may be the semiconductor laser element 20.

Blue light refers to light having an emission peak wavelength within a range from 420 nm to 494 nm. Green light refers to light having an emission peak wavelength within a range from 495 nm to 570 nm. Red light refers to light having an emission peak wavelength within a range from 605 nm to 750 nm.

The semiconductor laser element 20 emits laser light having directivity. Spreading divergent light is emitted from the light emission surface of the semiconductor laser element 20. The light emitted from the semiconductor laser element 20 forms a far field pattern (hereinafter referred to as an “FFP”) having an elliptical shape in a plane parallel to an exiting end surface of the light. The FFP indicates a shape and a light intensity distribution of the emitted light at a position spaced apart from the emission end surface.

Here, light passing through the center of the elliptical shape of the FFP, in other words, light having a peak intensity in the light intensity distribution of the FFP is referred to as light traveling on an optical axis or light passing through an optical axis. Based on the light intensity distribution of the FFP, light having an intensity of 1/e² or more with respect to a peak intensity value is referred to as a main portion of the light.

The FFP of the light emitted from the semiconductor laser element 20 has an elliptical shape that is longer in a layering direction than in a direction perpendicular to the layering direction in the plane parallel to the exiting end surface of the light. The layering direction is a direction in which a plurality of semiconductor layers including an active layer are layered in the semiconductor laser element 20. The direction perpendicular to the layering direction can also be referred to as a plane direction of the semiconductor layer. Further, a long diameter direction of the elliptical shape of the FFP can also be referred to as a fast axis direction of the semiconductor laser element 20, and a short diameter direction of the elliptical shape of the FFP can also be referred to as a slow axis direction of the semiconductor laser element 20.

Based on the light intensity distribution of the FFP, an angle at which light having a light intensity of 1/e² of a peak light intensity diverges is referred to as a divergence angle of light of the semiconductor laser element 20. For example, a divergence angle of light may also be determined from the light intensity at half the peak light intensity, for example, in addition to the light intensity at 1/e² of the peak light intensity. In the description herein, the term “divergence angle of light” by itself refers to a divergence angle of light at the light intensity of 1/e² of the peak light intensity. Note that it can be said that a divergence angle in the fast axis direction is greater than a divergence angle in the slow axis direction.

Examples of the semiconductor laser element 20 that emits blue light or the semiconductor laser element 20 that emits green light include a semiconductor laser element including a nitride semiconductor. A GaN-based semiconductor such as GaN, InGaN, and AlGaN, for example, can be used as the nitride semiconductor. Examples of the semiconductor laser element 20 that emits red light include a semiconductor laser element including an InAlGaP-based semiconductor, a GaInP-based semiconductor, or a GaAs-based semiconductor such as GaAs and AlGaAs.

### Submount 30

The submount 30 includes a substrate 31, a first metal layer 32, and a second metal layer 33. The submount 30 may further include a wiring layer 34.

The substrate 31 has a first surface 31A and a second surface 31B on the side opposite to the first surface 31A. In addition, the substrate 31 includes one or a plurality of lateral surfaces joined with the first surface 31A and the second surface 31B.

The substrate 31 has a shape, in plan view seen along the direction perpendicular to the first surface 31A, in which the width in one direction (hereinafter referred to as first direction) is smaller than the length in the direction perpendicular to the first direction (hereinafter referred to as second direction). For example, the substrate 31 has a cuboid shape. Note that it may not be a cuboid. The first surface 31A and the second surface 31B may have a rectangular shape with short sides and long sides. The short side direction may be the first direction, and the long side direction may be the second direction.

In the substrate 31, the height (thickness) between the first surface 31A and the second surface 31B is in a range from 100 μm to 300 μm. The width of the substrate 31 in the first direction is in a range from 500 μm to 1500 μm. The length of the substrate 31 in the second direction is in a range from 1000 μm to 2500 μm. Note that the size of the substrate 31 is not limited to the above.

The substrate 31 has an insulating property. The substrate 31 is formed of, for example, silicon nitride, aluminum nitride, or silicon carbide. It is preferable to select ceramic with relatively high heat dissipation as a main material of the substrate 31.

The first metal layer 32 is provided at the first surface 31A of the substrate 31. The first metal layer 32 may be provided directly, or indirectly with another component interposed therebetween, on the substrate 31. In the submount 30 illustrated in the drawing, the first metal layer 32 is directly provided on the first surface 31A of the substrate 31.

The second metal layer 33 is provided at the second surface 31B of the substrate 31. The second metal layer 33 may be provided directly, or indirectly with another component interposed therebetween, on the substrate 31. In the submount 30 illustrated in the drawing, the second metal layer 33 is directly provided on the second surface 31B of the substrate 31.

A metal such as copper and aluminum is used as a main material of the first metal layer 32. The height (thickness) of the first metal layer 32 in the direction perpendicular to the first surface 31A is in a range from 30 μm to 100 μm. In the submount 30, the first metal layer 32 is the thickest metal layer among one or a plurality of metal layers provided on the first surface 31A side of the substrate 31.

A metal such as copper and aluminum is used as a main material of the second metal layer 33. The second metal layer 33 may be formed of the same material as that of the first metal layer 32. The height (thickness) of the second metal layer 33 in the direction perpendicular to the second surface 31B is in a range from 30 μm to 100 μm. In the submount 30, the second metal layer 33 is the thickest metal layer among one or a plurality of metal layers provided on the second surface 31B side of the substrate 31.

The width of the second metal layer 33 in the first direction is smaller than that of the first metal layer 32. The difference between the length of the second metal layer 33 and the length of the first metal layer 32 in the second direction is smaller than the difference between the width of the second metal layer 33 and the width of the first metal layer 32 in the first direction.

The difference between the width of the first metal layer 32 and the width of the second metal layer 33 in the first direction is greater than 50 μm. The difference between the length of the first metal layer 32 and the length of the second metal layer 33 in the second direction is smaller than 50 μm. For example, the length of the second metal layer 33 in the second direction is the same as that of the first metal layer 32.

The width of the first metal layer 32 in the first direction is in a range from 85% to 100% of the width of the first surface 31A in the first direction. The length of the first metal layer 32 in the second direction is in a range from 90% to 100% of the length of the first surface 31A in the second direction. As viewed along the direction perpendicular to the first surface 31A, the first metal layer 32 is included in the first surface 31A.

The width of the second metal layer 33 in the first direction is in a range from 70% to 95% of the width of the second surface 31B in the first direction. The length of the second metal layer 33 in the second direction is in a range from 90% to 100% of the length of the second surface 31B in the second direction. As viewed along the direction perpendicular to the second surface 31B, the second metal layer 33 is included in the second surface 31B.

The area of the first metal layer 32 as viewed along the direction perpendicular to the first surface 31A is greater than the area of the second metal layer 33 as viewed along the direction perpendicular to the second surface 31B. The first metal layer 32 may be formed in a cuboid shape. The second metal layer 33 may be formed in a cuboid shape.

The thickness of the second metal layer 33 is in a range from 80% to 120% of the thickness of the first metal layer 32. Preferably, the thickness of the second metal layer 33 is in a range from 100% to 120% of the thickness of the first metal layer 32. By equalizing the thicknesses of the first metal layer 32 and the second metal layer 33, the stress can be balanced. Another idea is to make the second metal layer 33 relatively thicker, considering the difference in size between the first metal layer 32 and the second metal layer 33 in plan view.

The wiring layer 34 is provided on the first metal layer 32. The area of the wiring layer 34 as viewed along the direction perpendicular to the first surface 31A is smaller than the area of the second metal layer 33 as viewed along the direction perpendicular to the second surface 31B. The height (thickness) of the wiring layer 34 in the direction perpendicular to the first surface 31A is in a range from 300 nm to 1500 nm. The thickness of the wiring layer 34 can be one-tenth or less of the thickness of the first metal layer 32.

### Reflective Member 40

The reflective member 40 includes a lower surface, and a light reflective surface that reflects light. The light reflective surface is inclined to the lower surface. That is, the light reflective surface is neither perpendicular nor parallel in an arrangement relationship when viewed from the lower surface. A straight line connecting a lower end and an upper end of the light reflective surface is inclined to the lower surface of the reflective member 40. An angle of the light reflective surface with respect to the lower surface, or an angle of the straight line connecting the lower end and the upper end of the light reflective surface with respect to the lower surface is referred to as an inclination angle of the light reflective surface.

In the illustrated reflective member 40, the light reflective surface is a flat surface and forms an inclination angle of 45 degrees with respect to the lower surface of the reflective member 40. Note that the light reflective surface is not limited to a flat surface, and may be, for example, a curved surface. Further, the light reflective surface may not have an inclination angle of 45 degrees.

For the reflective member 40, glass, metal, or the like can be used as a main material. A heat-resistant material is preferably used as the main material, and for example, glass such as quartz or BK7 (borosilicate glass), or a metal such as aluminum can be used. The reflective member 40 can also be formed using Si as the main material. When the main material is a reflective material, the light reflective surface can be formed of the main material. When the light reflective surface is formed of a material different from the main material, the light reflective surface can be formed using, for example, metal such as Ag or Al, or a dielectric multilayer film such as Ta₂O₅/SiO₂, TiO₂/SiO₂, and Nb₂O₅/SiO₂.

On the light reflective surface, a reflectance for the peak wavelength of the light irradiated on the light reflective surface is 90% or more. The reflectance may be 95% or more. The reflectance can be 99% or more. The light reflectance is 100% or less or less than 100%.

### Protective Element 50

The protective element 50 prevents breakage of a specific element (the semiconductor laser element, for example) due to an excessive current flowing through the element. The protective element 50 is a Zener diode, for example. Further, a Zener diode formed of Si can be used as the Zener diode.

### Bonding Portion 60

The bonding portion 60 is a cured portion of a bonding material for bonding a plurality of components. The bonding portion 60 contains metal. The bonding portion 60 has conductivity. As the bonding material, pastes containing metal may be used, for example. As a specific example, pastes containing silver may be used. In addition, pastes containing gold or copper may also be used. A material that can be bonded at an ambient temperature of 250° C. or lower when the bonding process is performed is preferably used for the bonding material. This can reduce the risk of damaging the component due to high heat during the bonding process.

### Wiring Line 70

The wiring line 70 is a linear conductive material with bonding portions at both ends. The bonding portions at both ends are joint portions with other components. The wiring line 70 is, for example, a metal wire. For example, gold, aluminum, silver, copper, or the like can be used as the metal.

### Lid Member 80

The lid member 80 includes a lower surface and an upper surface, and is formed in a flat plate-like cuboid shape. Note that it may not be a cuboid. The lid member 80 has transmissivity for transmitting light. Here, the “transmissivity” means that a transmittance to light is 80% or more. Note that it does not necessarily have a transmittance of 80% or more for light of all wavelengths. The lid member 80 may partially include a non-light-transmissive region (a region with no transmissivity).

The lid member 80 is formed using glass as a main material. A main material of the lid member 80 is a material with high transmissivity. The lid member 80 is not limited to glass, and may be formed using, for example, sapphire as a main material.

### Lens Member 90

The lens member 90 includes an upper surface, a lower surface, and a lateral surface. The lens member 90 provides optical effects such as condensing, diffusing, and collimating to incident light, and light subjected to the optical effects is emitted from the lens member 90.

The lens member 90 includes one or a plurality of lens surfaces. The one or the plurality of lens surfaces are provided on the upper surface side of the lens member 90. Note that they may be provided on the lower surface side of the lens member 90. The upper surface and the lower surface are flat surfaces. The one or the plurality of lens surfaces meet the upper surface. The one or the plurality of lens surfaces are surrounded by the upper surface in the top view. In the top view, the lens member 90 has a rectangular external shape. The lower surface of the lens member 90 has a rectangular shape.

Of the lens member 90, a portion overlapping the one or the plurality of lens surfaces is a lens portion, and a portion that does not overlap the one or the plurality of lens surfaces is a non-lens portion in the top view. In the lens member 90, a portion overlapping the upper surface in the top view is included in the non-lens portion. A lens surface side when the lens portion is divided into two in a virtual plane including the upper surface is a lens-shape portion, and a lower surface side is a flat plate-like portion. The lower surface of the lens member 90 includes a lower surface of the lens portion and a lower surface of the non-lens portion.

The one or the plurality of lens surfaces of the lens member 90 are continuously formed in one direction. That is, the one or the plurality of lens surfaces are provided such that the lens surfaces are coupled with each other and are aligned in the same direction. The lens member 90 is formed such that a vertex of each lens surface is located on one virtual straight line. This virtual line is in the same direction as the X direction.

Here, in the top view, a direction in which the plurality of lens surfaces are aligned is referred to as a coupling direction. A length of the plurality of lens surfaces in the coupling direction is greater than a length in a direction perpendicular to the coupling direction in the top view. In the lens member 90 illustrated in the drawing, the coupling direction is in the same direction as the X direction.

The lens member 90 has transmissivity. The lens member 90 has transmissivity in both the lens portion and the non-lens portion. The lens member 90 can be formed using glass such as BK7.

The light-emitting device 100 will be described next.

### Light-Emitting Device 100

In the light-emitting device 100, the one or the plurality of semiconductor laser elements 20 are disposed on the mounting surface 11D of the base 10. The one or the plurality of semiconductor laser elements 20 are sealed in a package. The package forms a sealed space being an interior space in which the semiconductor laser element 20 is disposed. The package may be formed by bonding the lid member 80 to the base 10.

The semiconductor laser element 20 is mounted on the submount 30. The semiconductor laser element 20 is disposed on the side on which the first metal layer 32 of the submount 30 is provided. This improves heat dissipation for the heat generated from the semiconductor laser element 20. The semiconductor laser element 20 is disposed on the wiring layer 34. The semiconductor laser element 20 is bonded to the wiring layer 34 through a bonding material such as AuSn.

The semiconductor laser element 20 is mounted on the mounting surface 11D through the submount 30. The submount 30 is bonded to the base 10 on the side on which the second metal layer 33 is provided. Note that the side on which the first metal layer 32 is provided and the side on which the second metal layer 33 is provided can be specified with the substrate 31 as the boundary.

The one or the plurality of semiconductor laser elements 20 are disposed on the submounts 30 different from each other. One semiconductor laser element 20 is disposed on one submount 30. Note that a plurality of the semiconductor laser elements 20 may be disposed on one submount 30.

The semiconductor laser element 20 is disposed such that the light emission surface is disposed near the end portion or the lateral surface of the first metal layer 32 of the submount 30. The lateral surface of the first metal layer 32 located near the light emission surface is referred to as a first lateral surface 32A. In addition, the lateral surface of the first metal layer 32 on the side opposite to first lateral surface 32A is referred to as a second lateral surface 32B.

In the top view, the distance of the light emission surface of the semiconductor laser element 20 from the first lateral surface 32A may be in a range from −50 μm to +50 μm. The “−” as used herein means that the light emission surface is located inside the outer edge of the first metal layer 32 in the top view, and the “+” means that the light emission surface is located outside the outer edge. When the light emission surface is located on the “−” side, heat dissipation to the submount 30 increases. On the other hand, by positioning the light emission surface on the “+” side, the risk of the light from the semiconductor laser element 20 hitting the submount 30 before reaching the object can be reduced. When the light emission surface is disposed near the first lateral surface 32A, the disadvantages can be suppressed while achieving the advantages.

The first lateral surface 32A is a lateral surface extending in the short side direction of the submount 30 in the top view. In addition, the second lateral surface 32B is a lateral surface extending in the short side direction of the submount 30 in the top view. The semiconductor laser element 20 disposed on the submount 30 has a greater length in the second direction than the width in the first direction. In this manner, the short side directions of the semiconductor laser element 20 and the submount 30 can be aligned, and this contributes to reduction in size of the light-emitting device 100.

Each submount 30 is bonded to the base 10 by using a bonding material. Each submount 30 is bonded to the base 10 through the bonding portion 60 provided between the second metal layer 33 and the mounting surface 11D of the base 10. A portion of the bonding portion 60 bonding the submount 30 to the base 10 is formed at a position closer to the lateral side than the second metal layer 33. In the bonding process, the bonding material is pushed and crushed with the submount 30 and the base 10, and thus the bonding portion 60 is formed up to the lateral side of the second metal layer 33.

In the top view, the bonding portion 60 formed to bond the submount 30 reaches the outside of the outer edge of the submount 30. The fact that the bonding portion 60 reaches the outside of the submount 30 may be used as a condition for confirming that the submount 30 is sufficiently bonded to the base 10. Note that the bonding portion 60 may not reach the outside of the outer edge over the whole outer edge of the submount 30.

On the other hand, when the bonding portion 60 reaches the outside of the submount 30, the farther the position where the bonding portion 60 reaches from the submount 30, the larger the size of the light-emitting device 100. In view of this, by reducing the width of the second metal layer 33 in the first direction in comparison with the first metal layer 32 provided in a large range for heat dissipation, the protrusion of the bonding material can be kept at a closer position, which contributes to reduction in size of the light-emitting device 100.

The heat generated from the semiconductor laser element 20 tends to concentrate on the light emission surface and the lateral surface on the side opposite to the light emission surface. Thus, when the difference between the length of the first metal layer 32 and the length of the second metal layer 33 in the second direction is smaller than the difference between the width of the first metal layer 32 and the width of the second metal layer 33 in the first direction, the light-emitting device 100 can be made more compact while considering heat dissipation.

The width, in the first direction, of the first metal layer 32 of the submount 30 is greater than the width of the semiconductor laser element 20 in the first direction, and the width of the second metal layer 33 in the first direction is greater than the width of the semiconductor laser element 20 in the first direction. Accordingly, the light-emitting device 100 can be reduced in size while considering heat dissipation.

The length of the first metal layer 32 of the submount 30 in the second direction is greater than the length of the semiconductor laser element 20 in the second direction, and the length of the second metal layer 33 in the second direction is greater than the length of the semiconductor laser element 20 in the second direction.

The difference between the width of the first metal layer 32 and the width of the second metal layer 33 in the first direction is smaller than the width of the semiconductor laser element 20 in the first direction. It may be preferable to satisfy this condition in consideration of the effect on heat dissipation of making the second metal layer 33 smaller than the first metal layer 32.

The light-emitting device 100 may include the plurality of semiconductor laser elements 20. Further, the plurality of semiconductor laser elements 20 may be disposed side by side. When the submount 30 on which the semiconductor laser element 20 is disposed is one chip on submount (CoS), a plurality of the CoSs may be disposed side by side in the first direction in the light-emitting device 100. The plurality of submounts 30 are mounted on the mounting surface 11D of the base 10.

Each of the plurality of semiconductor laser elements 20 emits light in the second direction. Light of the FFP having a direction perpendicular to the mounting surface 11D as a fast axis direction is emitted from each of the light emission surfaces of the plurality of semiconductor laser elements 20. All of the semiconductor laser elements 20 have a divergence angle of 20 degrees or less in a slow axis direction. Note that the divergence angle is an angle greater than 0 degrees.

Each of the plurality of first semiconductor laser elements 20 emits light (hereinafter, referred to as first light) of a first color. Note that the plurality of first semiconductor laser elements 20 may include the semiconductor laser element 20 that emits light of a color different from that of the first light. The first color is red, for example. Note that the first color may not be red.

In the case in which the plurality of CoSs are disposed side by side in the light-emitting device 100, the smaller the distance between the submounts 30 adjacent to each other, the more compact the light-emitting device 100 can be in the first direction. On the other hand, when the distance between the submounts is close, the bonding material protruded by being pushed and crushed by the submounts, and the base is electrically connected to the semiconductor laser element disposed on the submount, resulting in a risk of generation of current leakage (see FIG. 10).

Making the width in the first direction of the second metal layer 33 smaller than of the first metal layer 32 contributes to reduction in size of the light-emitting device 100 in which CoSs are disposed side by side in the first direction. In the light-emitting device 100, the plurality of submounts 30 may be disposed side by side at an interval of 350 μm or less in the first direction. In addition, in the light-emitting device 100, the plurality of submounts 30 may be disposed side by side at an interval of 250 μm or less in the first direction.

In the case in which the CoSs are disposed close to each other and each CoS is mounted on the mounting surface 11D of the base 10 with a bonding material, the bonding material provided for bonding one of the submounts 30 adjacent to each other and the bonding material provided for bonding the other may mix between the submounts 30 adjacent to each other, and as a result, the bonding portion 60 may be formed higher than in the case in which the bonding portion 60 is formed with only one of the bonding materials.

In this case, the bonding portion 60 is preferably filled within the region E1 in cross-sectional view parallel to the first direction (see FIG. 8). The region E1 is surrounded by virtual planes respectively including the opposing lateral surfaces of the second metal layers 33 of the submounts 30 adjacent to each other, a virtual plane including the second surface 31B, and a virtual plane including the mounting surface 11D. This condition may be satisfied to make the light-emitting device 100 more compact. Note that the bonding portion 60 does not necessarily need to completely fill the region E1 (see FIG. 9).

Furthermore, the bonding portion 60 may not be completely filled within the region E2 in cross-sectional view parallel to the first direction (the region E2 see FIG. 10). The region E2 is surrounded by virtual planes respectively including the opposing lateral surfaces of the second metal layers 33 of the submounts 30 adjacent to each other, a virtual plane including the first surface 31A, and the mounting surface 11D. If the bonding portion 60 is completely filled up to the region E2, it is likely that the bonding portion 60 is formed above the first surface 31A, thus increasing the risk of current leakage. Note that the region E2 does not include the region where the submounts 30 (i.e., the substrates 31) are present.

In the light-emitting device 100, one or a plurality of reflective members 40 are disposed on the base 10. Each of the reflective members 40 is disposed on the mounting surface 11D. Light emitted from the one or the plurality of semiconductor laser elements 20 is reflected by the light reflective surface of the one or the plurality of reflective members 40. The light reflective surface is inclined to a traveling direction of light passing through an optical axis at an angle of 45 degrees. The light reflected by the light reflective surface travels upward.

The reflective member 40 can be provided in a one-to-one relationship with the semiconductor laser element 20. In other words, the reflective members 40 in the same number as the number of the semiconductor laser elements 20 may be disposed. In the light-emitting device 100, the plurality of reflective members 40 may be disposed side by side in the first direction in the top view. All of the reflective members 40 have the same size and shape.

The light reflective surface of the reflective member 40 reflects 90% or more of the irradiated main portion of light. Note that one reflective member 40 may be provided for the plurality of semiconductor laser elements 20. Alternatively, the light-emitting device 100 may not include the reflective member 40.

Regarding the submount 30 on which the semiconductor laser element 20 is disposed, in the top view, the distance between the submount 30, and the reflective member 40 irradiated with the light from the semiconductor laser element 20 is smaller than the distance between this submount 30 and the submount 30 adjacent to this submount 30. While the plurality of submounts 30 are bonded by applying the bonding material in the same manner, the submount 30 and the reflective member 40 do not need to be bonded in the same manner. Thus, when the distance between the submount 30 and the reflective member 40 can be set to a distance smaller than that of the submounts 30, the size of the light-emitting device 100 in the second direction can be reduced.

In the light-emitting device 100, the protective element 50 is mounted on the base 10. The protective element 50 is disposed on the upper surface of the stepped portion 12C of the base 10.

In the light-emitting device 100, the one or the plurality of semiconductor laser elements 20 are electrically connected to the base 10 through the plurality of wiring lines 70. The plurality of wiring lines 70 for electrically connecting the one or the plurality of semiconductor laser elements 20 to the base 10 include the wiring line 70 bonded to the wiring layer 13 provided to the first stepped portion 12C and the wiring line 70 bonded to the wiring layer 13 provided to the second stepped portion 12C.

In the light-emitting device 100, the lid member 80 is bonded to the base 10. The lid member 80 is disposed at the upper surface 11A of the base 10. In addition, the lid member 80 is located on the upper side of the stepped portion 12C. In addition, when the lid member 80 is bonded, a closed space defined by the base 10 and the lid member 80 is formed. This space is a space in which the semiconductor laser element 20 is disposed.

When the lid member 80 is bonded to the base 10 under a predetermined atmosphere, an air-tightly sealed closed space (seal space) is formed. By air-tightly sealing the space in which the semiconductor laser element 20 is disposed, quality deterioration due to dust collection can be suppressed. The lid member 80 has transmissivity to the light emitted from the semiconductor laser element 20. 90% or more of the main part of light emitted from the semiconductor laser element 20 is transmitted through the lid member 80 and emitted to the outside.

In the light-emitting device 100, the lens member 90 is fixed to the package. The lens member 90 is disposed on the upper side of the lid member 80. The lens member 90 is bonded to the lid member 80. Light emitted from each of the plurality of semiconductor laser elements 20 is emitted from the package and enters the lens member 90. The light transmitted through the lid member 80 enters the incidence surface of the lens member 90. The light incident on the incidence surface of the lens member 90 is emitted from the lens surface.

The number of the lens surfaces of the lens member 90 is the same as the number of the one or the plurality of semiconductor laser elements 20. The lens surfaces of the lens member 90 correspond to different semiconductor laser elements 20, and light emitted from the semiconductor laser elements 20 passes through corresponding lens surfaces. The main part of light emitted from the semiconductor laser elements 20 passes through lens surfaces that differ from each other and is emitted from the lens member 90. The light incident on the lens member 90 is emitted from the lens member 90 as collimated light, for example.

### Second Embodiment

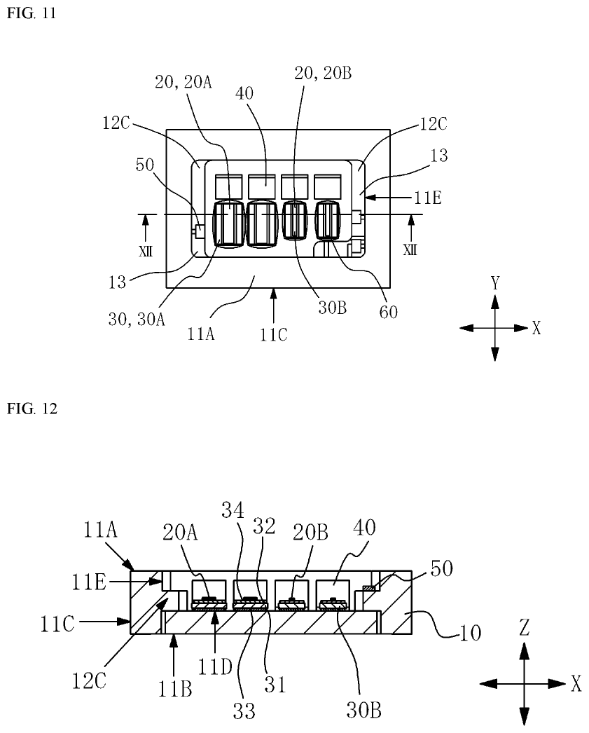

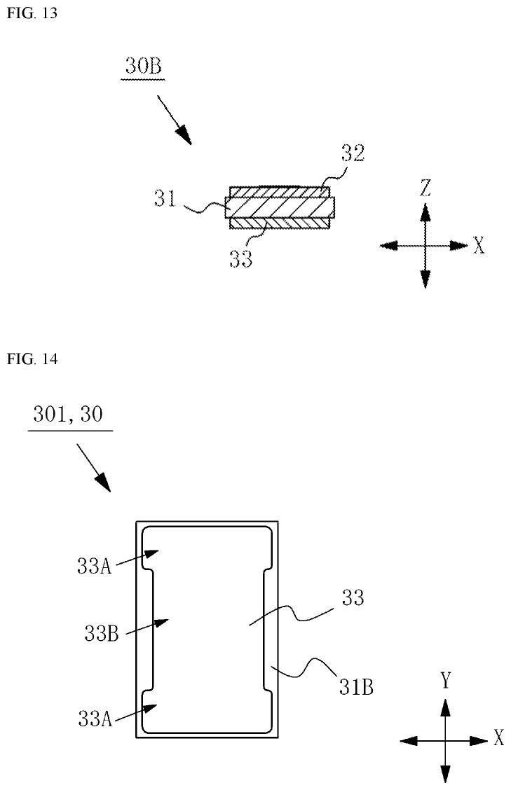

Next, a light-emitting device 101 according to a second embodiment will be described. FIGS. 1, 2, 5 to 7 and 11 to 13 are diagrams for illustrating an exemplary embodiment of the light-emitting device 101 according to the second embodiment. FIG. 1 is a perspective view of the light-emitting device 101. FIG. 2 is a top view of the light-emitting device 101. FIG. 5 is a top view of the mounting member 300 (first submount 30A). FIG. 6 is a cross-sectional view of the mounting member 300 taken along a cross-sectional line VI-VI of FIG. 5. FIG. 7 is a cross-sectional view of the mounting member 300 taken along a cross-sectional line VII-VII of FIG. 5. FIG. 11 is a top view for illustrating each component disposed inside the light-emitting device 101. FIG. 12 is a cross-sectional view taken along the line XII-XII in FIG. 11. FIG. 13 is an enlarged view of a second submount 30B in the cross-sectional view of FIG. 12.

The light-emitting device 101 includes a plurality of components. The plurality of components provided in the light-emitting device 100 include a base 10B, a plurality of semiconductor laser elements 20, one or a plurality of submounts 30 (hereinafter referred to as first submounts 30A), one or a plurality of second submounts 30B, one or a plurality of reflective members 40, one or a plurality of protective elements 50, one or a plurality of bonding portions 60, a plurality of wiring lines, a lid member 80, and a lens member 90.

The light-emitting device 101 is different from the light-emitting device 100 in that the base 10B is provided instead of the base 10. The light-emitting device 101 includes the plurality of semiconductor laser elements 20 including a first semiconductor laser element 20A and a second semiconductor laser element 20B, and the second submount 30B in addition to the submount 30.

Of the description for the light-emitting device 100 and each component of the above-described first embodiment, all the contents, excluding the contents that can be said to be contradictory from FIGS. 1, 2, 5 to 7 and 11 to 13 related to the light-emitting device 101, are also applicable to the description of the light-emitting device 101. All non-contradictory contents are not described here again to avoid duplication. Note that the description for the base 10 of the first embodiment applies to the description of the base 10B to the extent that it is not contradictory.

### Light-Emitting Device 101

In the light-emitting device 101, the plurality of semiconductor laser elements 20 include one or a plurality of the first semiconductor laser elements 20A and one or a plurality of the second semiconductor laser elements 20B. The first semiconductor laser element 20A is the semiconductor laser element 20 that emits first light. The second semiconductor laser element 20B is the semiconductor laser element 20 that emits light different from the first light.

The one or the plurality of second semiconductor laser elements 20B include the semiconductor laser element 20 that emits light of a second color (hereinafter referred to as second light). The second light is light of color different from that of the first light. The second color is blue, for example. Note that the second color may not be blue.

Furthermore, the plurality of second semiconductor laser elements 20B may include the semiconductor laser element 20 that emits light of a third color (hereinafter referred to as third light). The third light is light of a color different from the colors of the first light and second light. The third color is green, for example. Note that the third color may not be green.

The first light, second light, and the third light are light with colors different from each other, and the colors are selected from red, green, and blue. The light-emitting device 101 can emit RGB light.

The base 10B includes the stepped portion 12C formed along not only one inner lateral surface 11E but also two joined inner lateral surfaces 11E. In the light-emitting device 101, the semiconductor laser elements 20 that emit light of different colors may be driven independently. The stepped portion 12C formed along two inner lateral surfaces 11E makes it easier to provide the plurality of wiring layers 13 on the stepped portion 12C.

In the light-emitting device 101, the first semiconductor laser element 20A is disposed at the first submount 30A, and the second semiconductor laser element 20B is disposed at the second submount 30B. The second submount 30B includes the substrate 31 having an insulating property, the first metal layer 32, and the second metal layer 33.

In the second submount 30B, the difference between the width of the second metal layer 33 and the width of the first metal layer 32 in the first direction is smaller than 50 μm. In the second submount 30B, the difference between the length of the second metal layer 33 and the length of the first metal layer 32 in the second direction is smaller than 50 μm. The first metal layer 32 and the second metal layer 33 of the second submount 30B illustrated in the drawing have the same widths in the first direction and the second direction same.

The width of the second submount 30B in the first direction is smaller than that of the first submount 30A. The length of the second submount 30B in the second direction may be smaller than that of the first submount 30A.

In the light-emitting device 101, the first submount 30A and the second submount 30B are disposed side by side in the first direction. The first submount 30A and the first submount 30A may be disposed side by side in the first direction. The second submount 30B and the second submount 30B may be disposed side by side in the first direction.

The distance between the first submount 30A and the second submount 30B disposed adjacent to each other is greater than the distance between the first submount 30A and the first submount 30A disposed adjacent to each other. Alternatively, the distance between the first submount 30A and the second submount 30B disposed adjacent to each other is smaller than the distance between the second submount 30B and the second submount 30B disposed adjacent to each other.

In the light-emitting device 101 illustrated in the drawing, the distance becomes larger in the order of the distance between the first submount 30A and the first submount 30A disposed adjacent to each other, the distance between the first submount 30A and the second submount 30B disposed adjacent to each other, the distance between the second submount 30B and the second submount 30B disposed adjacent to each other. This condition may be applied to the submounts when light is emitted at approximately even intervals from the plurality of semiconductor laser elements 20 disposed side by side in the first direction. Then, when the distance between the submounts adjacent to each other increases, the first metal layer 32 and the second metal layer 33 can be formed in the same shape, and the second submount 30B has a structure superior in heat dissipation to the first submount 30A can be employed.

Note that, for example, when a plurality of submounts with different sizes in the top view are used because of the different sizes of the semiconductor laser elements to be disposed, the amount of the bonding material required for bonding the submounts may differ depending on the sizes. The amount of the bonding material applied to bond the second submount 30B to the mounting surface 11D of the base 10B is less than the amount of the bonding material applied to bond the first submount 30A to the mounting surface 11D of the base 10B. This may also be a motivation for employing the second submount 30B, which has a better structure for heat dissipation than the first submount 30A.

The second semiconductor laser elements 20B are each disposed on a different second submount 30B. One second semiconductor laser element 20B is disposed on one second submount 30B. Note that the plurality of second semiconductor laser elements 20B may be disposed on one second submount 30B.

### Variations of Mounting Member

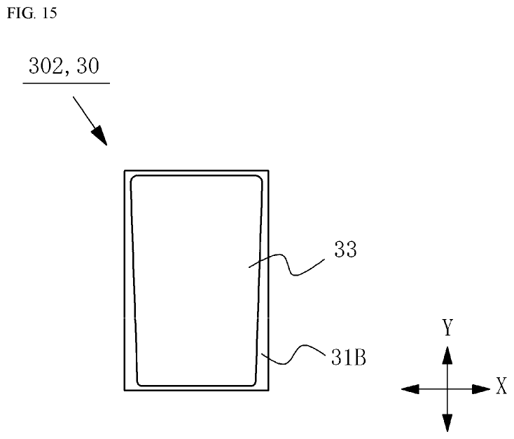

Next, variations of the mounting member 300 described in the first embodiment and second embodiment will be described. FIG. 14 is a schematic view for illustrating the second metal layer 33 of a mounting member 301 according to the variation. FIG. 15 is a schematic view for illustrating the second metal layer 33 of a mounting member 302 according to the variation. FIG. 5 is a schematic view for illustrating the first metal layer 32 of the mounting members 301 and 302 according to the variation. Each of the mounting members 301 and 302 according to the variation may be employed as the submount 30 for the light-emitting device 100 and the light-emitting device 101.

Of the description for the submount 30 in the first embodiment and the second embodiment, all the contents, excluding the contents that can be said to be contradictory from FIG. 14 or FIG. 15, are also applicable to the descriptions of the mounting members 301 and 302 according to the variation. All non-contradictory contents are not described here again to avoid duplication.

### Mounting Member 301

The mounting member 301 is different from the mounting member 300 in that the second metal layer 33 has a portion with a smaller width in the first direction than the first metal layer 32. In the mounting member 300, the width of the second metal layer 33 in the first direction is smaller than that of the first metal layer 32 over the entire length in the second direction, whereas in the mounting member 301, the width in the first direction is the same as that of the first metal layer 32 at both end portions of the second metal layer 33 in the second direction.

Note that although the second metal layer 33 of the mounting member 301 does not need to have the same width in the first direction as the first metal layer 32 at the end portions in the second direction, the second metal layer 33 includes a wide portion 33A with a relatively wide width in the first direction and a narrow portion 33B with a relatively narrow width in the first direction.

At least one of both end portions of the second metal layer 33 in the second direction is the wide portion 33A. In the light-emitting device in which the semiconductor laser element 20 is disposed, it is preferable that the end portion on the side close to the light emission surface be the wide portion 33A. By forming the second metal layer 33 with a wider end portion close to the light emission surface where heat concentrates, the mounting member may be made more excellent in heat dissipation. In the mounting member 301 illustrated in the drawing, the end portion close to the light emission surface is the end portion on the Y positive direction side.

The wide portion 33A may be provided at both end portions of the second metal layer 33 in the second direction. Since the heat concentrates not only at the light emission surface, but also at the lateral surface on the side opposite to the light emission surface in the semiconductor laser element 20, a mounting member is made more excellent in heat dissipation by providing the wide portion 33A at both end portions and the narrow portion 33B at the center portion between the both end portions.

The length of the narrow portion 33B in the second direction is greater than the length of the wide portion 33A in the second direction. As a result, the region for suppressing the protrusion of the bonding material can be sufficiently ensured. Furthermore, the length of the narrow portion 33B in the second direction may be greater than the sum of the lengths in the second direction of the wide portions 33A provided at both end portions.

### Mounting Member 302

In the second metal layer 33 in the mounting member 302, the width in the first direction decreases stepwise from one end toward the other end in the second direction. In the mounting member 302 illustrated in the drawing, the width in the first direction continuously decreases from one end toward the other end in the second direction.

In the second metal layer 33 of the mounting member 302, the width in the first direction is smaller at the other end than at one end of the two ends in the second direction. Here, in the case in which the mounting member 302 is employed for a light-emitting device in which the semiconductor laser element 20 is disposed, it is desirable that one end (with larger width) be an end closer to the light emission surface. Comparing the light emission surface and the opposite surface in the semiconductor laser element 20, the heat concentrates more on the light emission surface, and therefore, by disposing the semiconductor laser element 20 on the mounting member 302 as described above, a light-emitting device can be made more excellent in heat dissipation.

### Third Embodiment

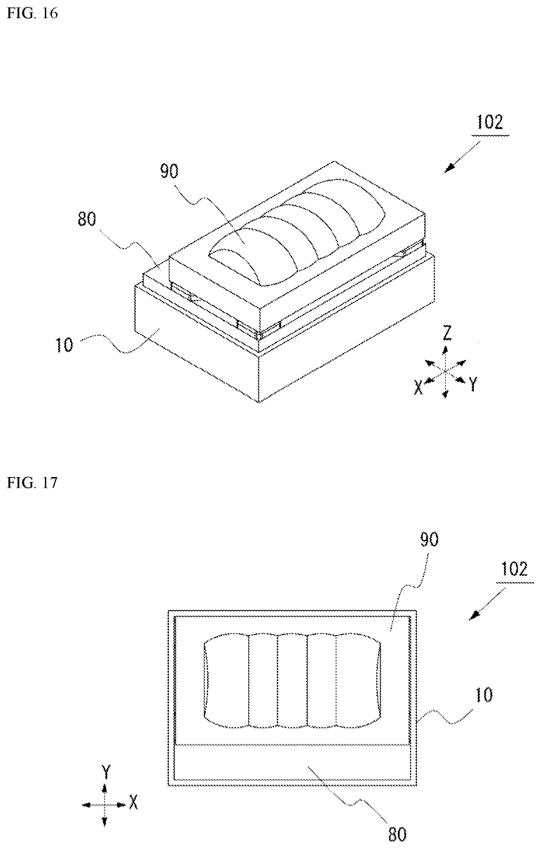

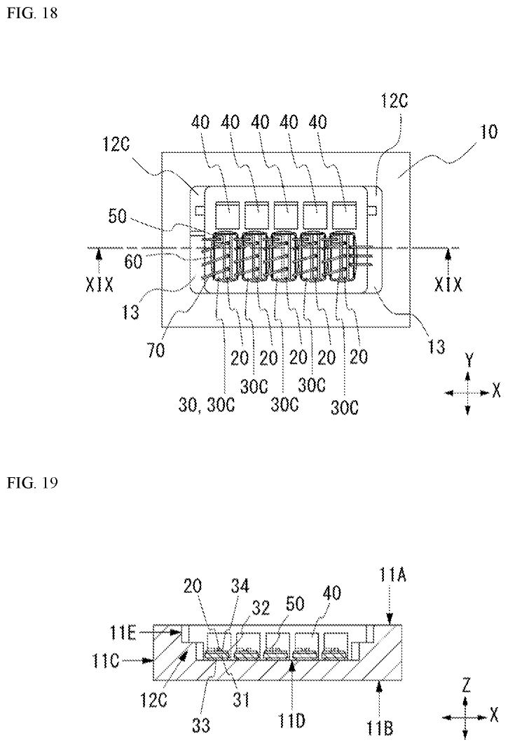

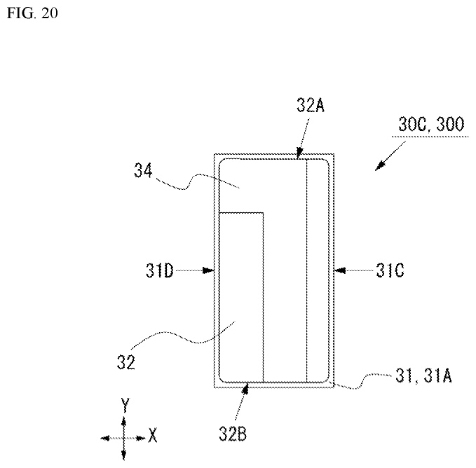

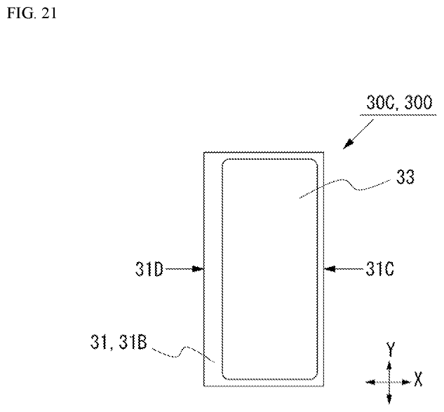

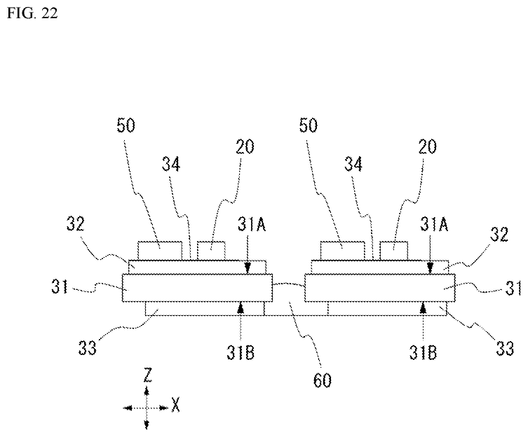

Next, a light-emitting device 102 according to the third embodiment will be described. FIGS. 16 to 22 are diagrams for illustrating exemplary embodiments of the light-emitting device 102 according to the third embodiment. FIG. 16 is a perspective view of the light-emitting device 102. FIG. 17 is a top view of the light-emitting device 102. FIG. 18 is a top view for illustrating each component disposed inside the light-emitting device 102. FIG. 19 is a cross-sectional view taken along a cross-sectional line XIX-XIX of FIG. 18. FIG. 20 is a top view of a mounting member 303 (a third submount 30C). FIG. 21 is a bottom view of the mounting member 303. FIG. 22 is a schematic view for illustrating an example of a state of bonding the submount 30 in the light-emitting device 102.

The light-emitting device 102 includes a plurality of components. The plurality of components provided in the light-emitting device 102 include a base 10B, a plurality of semiconductor laser elements 20, a plurality of submounts 30 (hereinafter referred to as third submount 30C), one or a plurality of reflective members 40, one or a plurality of protective elements 50, one or a plurality of bonding portions 60, a plurality of wiring lines, a lid member 80, and a lens member 90.

The light-emitting device 102 is different from the light-emitting device 100 and the light-emitting device 101 in that the third submount 30C is provided as the submount 30 instead of the first submount 30A. Note that the light-emitting device 102 may include the first submount 30A or the second submount 30B. The number of the semiconductor laser elements 20 mounted in the light-emitting devices 102 is larger than that of the light-emitting device 100 and the light-emitting device 101, and accordingly the number of the lens surfaces of the lens member 90 is also greater.

Of the description for the light-emitting device 100, the light-emitting device 101, and each component of the above-described first embodiment, all the contents, excluding the contents that can be said to be contradictory from FIGS. 16 to 22 related to the light-emitting device 102, are also applicable to the description of the light-emitting device 102. All non-contradictory contents are not described here again to avoid duplication.

### Third Submount 30C

In the plan view as seen along the direction perpendicular to the first surface 31A (hereinafter referred to as plan view), in the third submount 30C, the middle point of the width of the second metal layer 33 in the first direction (hereinafter referred to as second middle point) is shifted (or offset) in the first direction from the middle point of the width of the first metal layer 32 in the first direction (hereinafter referred to as first middle point). Note that the state of being “shifted (or offset) in the first direction” does not depend on whether the first middle point and the second middle point are shifted in the second direction. In the plan view, the distance from the middle point of the width of the substrate 31 in the first direction to the first middle point is smaller than the distance from the middle point of the width of the substrate 31 in the first direction to the second middle point.

In the plan view, of the two lateral surfaces of the substrate 31 extending in the long side direction, the distance from one lateral surface (hereinafter referred to as first lateral surface 31C) to the second metal layer 33 in the first direction (hereinafter referred to as first distance) is smaller than the distance from the other lateral surface (hereinafter referred to as second lateral surface 31D) to the second metal layer 33 in the first direction (hereinafter referred to as second distance). In the plan view, the first distance is greater than the distance from the first lateral surface to the first metal layer 32 in the first direction (hereinafter referred to as third distance).

The difference between the first distance and the second distance may be in a range from 10 μm to 250 μm. The second distance may be in a range from 20 μm to 350 μm. The difference between the first distance and the third distance may be in a range from 0 μm 50 μm.

### Light-Emitting Device 102

In the light-emitting device 102, a plurality of the third submounts 30C are disposed side by side in the first direction. The plurality of third submounts 30C are disposed such that, in two third submounts 30C adjacent to each other, the first lateral surface 31C of the substrate 31 of one third submount 30C and the second lateral surface 31D of the substrate 31 of the other third submount 30C face each other. This arrangement can suppress the protrusion of the bonding material in the same manner as in the light-emitting device 100, and can contribute to the reduction in size of the light-emitting device.

In the semiconductor laser element 20, the middle point of the width in the first direction of the semiconductor laser element 20 is disposed at a position shifted in the first direction from the middle point of the width in the first direction of the substrate 31 of the third submount 30C on which the semiconductor laser element 20 is disposed. The semiconductor laser element 20 is disposed at a position shifted to the direction of the second middle point from the middle point of the substrate 31 in the first direction. The second metal layer 33 is also shifted from the center of the substrate 31 in accordance with the semiconductor laser element 20 disposed on the third submount 30C at a position shifted from the center of the substrate 31 in the first direction, and thus the heat-dissipation property can be improved.

In the top view, the distance, in the first direction, from the first lateral surface 31C of the substrate 31 of the third submount 30C to the semiconductor laser element 20 disposed at that third submount 30C is smaller than the distance from the second lateral surface 31D of the substrate 31 of that third submount 30C to that semiconductor laser element 20 in the first direction.

In the top view, the area of the larger region of the two regions obtained by dividing the second metal layer 33 by a virtual line that passes through the middle point of the substrate 31 in the first direction and is parallel to the second direction is greater than the area of the larger region of the two regions obtained by dividing the second metal layer 33 by a virtual line that passes through the middle point of the semiconductor laser element 20 disposed at the third submount 30 in the first direction and is parallel to the second direction.

In the top view, in comparison with the distance from the first middle point of the third submount 30C to the semiconductor laser element 20 disposed on this third submount 30C, the distance from the second middle point of that third submount 30C to that semiconductor laser element 20 is smaller.

In the top view, the center of the second metal layer 33, which is the middle point of the second metal layer 33 in the first direction and is the middle point in the second direction, overlaps the semiconductor laser element 20. Note that in the top view, the center of the second metal layer 33 may not overlap the semiconductor laser element 20. In the top view, the center of the first metal layer 32, which is the middle point of the first metal layer 32 in the first direction and is the middle point in the second direction, does not overlap the semiconductor laser element 20.

Note that the third submount 30C is another example of the mounting member 300. The technique of the mounting member 301 or the mounting member 302 according to the above-described variation may be further applied to the third submount 30C.

While the embodiments of the present invention are described above, the light-emitting device and the mounting member according to the present invention are not limited to the light-emitting device and the mounting member of the embodiments. Specifically, the present invention may be implemented without being limited the external shapes and structures of the light-emitting device and the mounting member described in the embodiments. The present invention may be applied without requiring all the components being sufficiently provided. For example, in a case in which some of the components of the light-emitting module disclosed by the embodiments are not stated in the scope of the claims, the degree of freedom in design by those skilled in the art such as substitutions, omissions, shape modifications, and material changes for those components is allowed, and then the invention stated in the scope of the claims being applied to those components is specified.

Throughout the contents described in this description, the following aspects are disclosed.

### Aspect 1

A light-emitting device includes a semiconductor laser element, and a submount including a substrate having an insulating property, a first metal layer, and a second metal layer, the submount being provided with the semiconductor laser element on a side where the first metal layer is provided. The substrate having the insulating property has a first surface and a second surface located on a side opposite to the first surface, and has a shape in which a length in a second direction perpendicular to a first direction is greater than a width in the first direction in a plan view as seen along a direction perpendicular to the first surface, the first metal layer is provided on the first surface, the second metal layer is provided on the second surface and has a smaller width in the first direction than the first metal layer, and a difference between a length of the first metal layer and a length of the second metal layer in the second direction is smaller than a difference between a width of the first metal layer and a width of the second metal layer in the first direction.

### Aspect 2

The light-emitting device according to Aspect 1, wherein the difference between the width of the first metal layer and the width of the second metal layer in the first direction is greater than 50 μm, and the difference between the length of the first metal layer and the length of the second metal layer in the second direction is smaller than 50 μm.

### Aspect 3

The light-emitting device according to Aspect 1 or 2, wherein a length of the semiconductor laser element in the second direction is greater than a width of the semiconductor laser element in the first direction.

### Aspect 4

The light-emitting device according to any one of Aspects 1 to 3, wherein the submount includes a wiring layer provided on the first metal layer.

### Aspect 5

The light-emitting device according to any one of Aspects 1 to 4, wherein a thickness of the first metal layer is 30 μm or more.

### Aspect 6

The light-emitting device according to any one of Aspects 1 to 5, wherein a thickness of the second metal layer is 30 μm or more.

### Aspect 7

The light-emitting device according to any one of Aspects 1 to 6, wherein the width of the first metal layer and the width of the second metal layer in the first direction are each greater than a width of the semiconductor laser element in the first direction.

### Aspect 8

The light-emitting device according to any one of Aspects 1 to 7, wherein the difference between the width of the first metal layer and the width of the second metal layer in the first direction is smaller than a width of the semiconductor laser element in the first direction.

### Aspect 9

The light-emitting device according to any one of Aspects 1 to 8, wherein the submount on which the semiconductor laser element is disposed is one of a plurality of submounts on which the semiconductor laser element is disposed, and the plurality of submounts are disposed side by side in the first direction.

### Aspect 10

The light-emitting device according to Aspect 9, further includes a base having a mounting surface on which the plurality of submounts disposed side by side in the first direction are mounted, wherein the plurality of submounts are disposed at an interval of 1500 μm or less in the first direction.

### Aspect 11

The light-emitting device according to Aspect 10, further includes a bonding portion provided between the mounting surface and the second metal layer of each of the plurality of submounts and configured to bond the submount to the base, wherein in a cross-sectional view parallel to the first direction, the bonding portion is filled within a region surrounded by virtual planes respectively including facing lateral surfaces of the second metal layers of the plurality of submounts adjacent to each other, the second surface, and the mounting surface.

### Aspect 12

The light-emitting device according to Aspect 10, further includes a bonding portion provided between the mounting surface and the second metal layer of each of the plurality of submounts and configured to bond the submount to the base, wherein the bonding portion is filled within a region surrounded by virtual planes respectively including facing lateral surfaces of the second metal layers of the submounts adjacent to each other, the second surface, and the mounting surface in a cross-sectional view parallel to the first direction, and is not filled within region surrounded by virtual planes respectively including the facing lateral surfaces of the second metal layers of the submounts adjacent to each other, the first surface, and the mounting surface.

### Aspect 13

The light-emitting device according to any one of Aspects 1 to 12, wherein the semiconductor laser element is disposed such that a middle point of a width of the semiconductor laser element in the first direction is disposed at a position shifted in the first direction from a middle point of the width of the substrate having the insulating property in the first direction, and in the plan view as seen along the direction perpendicular to the first surface, a middle point of the width of the second metal layer in the first direction is shifted in the first direction from a middle point of the width of the first metal layer in the first direction.

The light-emitting device according to the embodiments can be used for projectors, in-vehicle headlights, head-mounted displays, lighting, displays and the like.

What is claimed is:

1. A light-emitting device comprising:
a submount including
a substrate having an insulating property, and having a first surface and a second surface located on a side opposite to the first surface, the substrate having a shape in which a length in a second direction perpendicular to a first direction is greater than a width in the first direction in a plan view as seen along a direction perpendicular to the first surface,
a first metal layer arranged on the first surface of the substrate, and
a second metal layer arranged on the second surface of the substrate; and
a semiconductor laser element arranged on a side of the submount on which the first metal layer is arranged, wherein
a width of the second metal layer is smaller than a width of the first metal layer in the first direction, and
a difference between a length of the first metal layer and a length of the second metal layer in the second direction is smaller than a difference between the width of the first metal layer and the width of the second metal layer in the first direction.

2. The light-emitting device according to claim 1, wherein
the difference between the width of the first metal layer and the width of the second metal layer in the first direction is greater than 50 μm; and
the difference between the length of the first metal layer and the length of the second metal layer in the second direction is smaller than 50 μm.

3. The light-emitting device according to claim 1, wherein
the semiconductor laser element has a shape in which a length of the semiconductor laser element in the second direction is greater than a width of the semiconductor laser element in the first direction.

4. The light-emitting device according to claim 1, wherein
the submount includes a wiring layer arranged on the first metal layer.

5. The light-emitting device according to claim 1, wherein
a thickness of the first metal layer is 30 μm or more.

6. The light-emitting device according to claim 5, wherein
a thickness of the second metal layer is 30 μm or more.

7. The light-emitting device according to claim 1, wherein
each of the width of the first metal layer and the width of the second metal layer in the first direction is greater than a width of the semiconductor laser element in the first direction.

8. The light-emitting device according to claim 1, wherein
the difference between the width of the first metal layer and the width of the second metal layer in the first direction is smaller than a width of the semiconductor laser element in the first direction.

9. The light-emitting device according to claim 1, further comprising:
a plurality of submounts including the submount; and
a plurality of semiconductor laser elements including the semiconductor laser element, the plurality of semiconductor laser elements being respectively arranged on the plurality of submounts, wherein
the plurality of submounts are disposed side by side in the first direction.

10. The light-emitting device according to claim 9, further comprising
a base having a mounting surface on which the plurality of submounts are disposed, wherein
the plurality of submounts are disposed at an interval of 350 μm or less in the first direction.

11. The light-emitting device according to claim 10, further comprising
a bonding portion arranged between the mounting surface and the second metal layer of each of the plurality of submounts and configured to bond the submounts to the base, wherein
in a cross-sectional view parallel to the first direction, the bonding portion is disposed within a region surrounded by virtual planes respectively including opposing lateral surfaces of the second metal layers of adjacent ones of the plurality of submounts, a virtual plane including the second surface, and a virtual plane including the mounting surface.

12. The light-emitting device according to claim 10, further comprising
a bonding portion provided between the mounting surface and the second metal layer of each of the plurality of submounts and configured to bond the submount to the base, wherein
in a cross-sectional view parallel to the first direction,
the bonding portion is filled within a region surrounded by virtual planes respectively including opposing lateral surfaces of the second metal layers of adjacent ones of the submounts, a virtual plane including the second surface, and a virtual plane including the mounting surface, and
the bonding portion is not completely filled within a region surrounded by virtual planes respectively including opposing lateral surfaces of the second metal layers of the submounts adjacent to each other, a virtual plane including the first surface, and the virtual plane including the mounting surface.

13. The light-emitting device according to claim 1, wherein
the semiconductor laser element is disposed such that a middle point of a width of the semiconductor laser element in the first direction is disposed at a position shifted in the first direction from a middle point of the width of the substrate in the first direction, and
in the plan view, a middle point of the width of the second metal layer in the first direction is shifted in the first direction from a middle point of the width of the first metal layer in the first direction.

14. A mounting member comprising:
a substrate having an insulating property and having a first surface and a second surface on a side opposite to the first surface, the substrate having a shape in which a length in a second direction perpendicular to a first direction is greater than a width in the first direction in a plan view as seen along a direction perpendicular to the first surface;
a first metal layer arranged on the first surface; and
a second metal layer arranged on the second surface, wherein
a width of the second metal layer is smaller than a width of the first metal layer in the first direction, and
a difference between a length of the first metal layer and a length of the second metal layer in the second direction is smaller than a difference between the width of the first metal layer and the width of the second metal layer in the first direction.

15. The mounting member according to claim 14, wherein
in the plan view, a middle point of the width of the second metal layer in the first direction is shifted in the first direction from a middle point of the width of the first metal layer in the first direction.
